(19) United States
(12) Patent Application Publication
(10) Pub. No.: US 2025/0216160 A1
(43) Pub. Date: Jul. 3, 2025

(54) LIQUID COOLING DEVICE AND WATER-LIQUID SEPARATION MODULE THEREOF

(71) Applicant: WE SOLUTIONS TECHNOLOGY CO., LTD, Taoyuan City (TW)

(72) Inventors: CHUNG-PENG HUANG, Taoyuan City (TW); FANG-YI LIN, Taoyuan City (TW); KUAN-LIN CHEN, Taoyuan City (TW); CHUN-CHING KUO, Taoyuan City (TW); TZU-YUAN YEN, Taoyuan City (TW)

(21) Appl. No.: 18/587,988

(22) Filed: Feb. 27, 2024

(30) Foreign Application Priority Data
Dec. 28, 2023 (TW) 112151324

(51) Int. Cl. F28F 17/00; H05K 7/20

(52) U.S. Cl. CPC F28F 17/00; H05K 7/203; H05K 7/20318; H05K 7/20327

(57) ABSTRACT

A liquid cooling device and a water-liquid separation module thereof for solving a conventional issue of difficulties in removing water-liquid vapor mixed into a cooling tank. The water-liquid separation module includes a separation tank, including from top to bottom a mixed liquid inlet section, a water-liquid outlet section and a cooling liquid outlet section. The separation tank has a boundary line. The mixed liquid inlet section is higher than the boundary line. The water-liquid outlet section and the cooling liquid outlet section are lower than the boundary line. A valve assembly, includes a first valve disposed at the mixed liquid inlet section, a drain valve disposed at the water-liquid outlet section, and a second valve disposed at the cooling liquid outlet section.

### CROSS-REFERENCE TO RELATED APPLICATION

This non-provisional application claims priority under 35 U.S.C. § 119(a) on Patent Application No(s). 112151324 filed in Taiwan, R.O.C. on Dec. 28, 2023, the entire contents of which are hereby incorporated by reference.

### BACKGROUND OF THE INVENTION

### 1. Field of the Invention

The present disclosure relates to a cooling device and a component thereof, and in particular to a liquid cooling device and a water-liquid separation module thereof.

### 2. Description of the Related Art

In industrial processes or high-performance computing devices, gases with environmental pollution or health hazards frequently need to be used. To prevent related gas leakage or waste, it is necessary for cabinets of related apparatuses or devices be designed with good airtightness.

For example, accompanied with rapid increases in powers and heat flux densities of heating components of electronic elements related to computing in computers, immersion cooling is one of the most effective techniques to quickly reduce the amount of heat generated by electronic computing elements. In two-phase immersion cooling, phase change heat transfer is performed in an enclosed space of a cabinet, and a coolant (such as perfluoro-ketone approaching a boiling point of 50° C.) boils and becomes a gaseous coolant. The gaseous coolant is condensed through a condenser tube above, transforms back into a liquid and returns to a lower part. Thus, without needing to provide additional resources or pump power for heat dissipation, an effect of coolant circulation is achieved.

### BRIEF SUMMARY OF THE INVENTION

However, during maintenance or element replacement of the two-phase immersion cooling device above, an upper lid of the cooling device is opened. To prevent a gaseous coolant from spreading to a factory area or a machine room or further escaping into the air, an outer hood is usually used for separation. However, when the upper lid is opened, air containing water-liquid vapor in the outer hood is mixed into the gaseous coolant. Thus, after an element has been replaced and the upper lid of the cooling device is closed, part of the air containing water-liquid vapor remains in the cooling device, causing a risk of electrical conduction due to condensed water-liquid.

In view of the above, the present disclosure provides a liquid cooling device and a water-liquid separation module thereof applicable to receiving a condensed mixed liquid and separating a cooling liquid and water-liquid, so as to recollect the cooling liquid and discharge the water-liquid.

The directional or similar terms used throughout the literature of the present disclosure, for example, “front”, “back/rear”, “left”, “right”, “up/upper/top”, “down/lower/bottom”, “in/inner”, “out/outer” and “side surface”, are primarily given with reference to the directions of the drawings. These directional or similar terms are intended to assist in describing and better understanding various embodiments of the present disclosure and are not to be construed as limitations to the present disclosure. Regarding the description related to a liquid, one that passes through first is referred to as “front”, and one that passes later is referred to as “back”.

The articles “a/an” and “one” used for the elements and components described throughout the literature of the present disclosure are merely for the ease of use and to provide common meanings of the scope of the present disclosure, and should be interpret as “one” or “at least one” in the present disclosure. Moreover, the concept of a singular form also includes cases of plural forms, unless otherwise specified.

Similar terms including “join”, “combine”, “couple” or “assemble” used throughout the literature of the present disclosure primarily include forms which can be separated without sabotaging the components or contain inseparable components once connected, and can be selected by a person skilled in the art according to materials or assembly requirements of the components to be connected.

To achieve the above and other objects, the present disclosure provides a water-liquid separation module, including: a separation tank, including from top to bottom a mixed liquid inlet section, a water-liquid outlet section and a cooling liquid outlet section, the separation tank having a boundary line, the mixed liquid inlet section being higher than the boundary line, the water-liquid outlet section and the cooling liquid outlet section being lower than the boundary line; and a valve assembly, including a first valve disposed at the mixed liquid inlet section, a drain valve disposed at the water-liquid outlet section, and a second valve disposed at the cooling liquid outlet section.

The present disclosure further provides a liquid cooling device, including: a cooling tank, having a cooling zone and a condensation zone at an interior thereof, the cooling zone configured to accommodate a cooling liquid, and the condensation zone located above the cooling zone; a condensation module, disposed in the condensation zone; a liquid collection tank, located above the cooling zone, configured to receive a liquid condensed by the condensation module; and the water-liquid separation module above, in communication with the liquid collection tank via the mixed liquid inlet section, and in communication with the cooling zone via the cooling liquid outlet section.

In the water-liquid separation module above, the water-liquid outlet section may be disposed to be slightly lower than the boundary line.

In the water-liquid separation module above, the separation tank may include an inspection window. The inspection window may be located between the first valve and the second valve, and may be at least partially higher than the boundary line.

The water-liquid separation module above may further include a liquid retrieval container. The liquid retrieval container is detachably combined at the water-liquid outlet section, and the drain valve can control whether the liquid retrieval container is in communication with the interior of the separation tank.

The liquid cooling device above may further include a storage tank. The storage tank may be located in the cooling tank and may be in communication with the liquid collection tank and located below the liquid collection tank, and the mixed liquid inlet section may be in communication with a lower half of the storage tank.

The liquid cooling device above may further include an S-shaped bend pipe. The S-shaped bend pipe may be located in the cooling tank, and may have one end thereof in communication with the lower half of the storage tank. The S-shaped bend pipe has an uppermost part between two ends thereof, and the uppermost part may be aligned with an upper half of the storage tank.

The liquid cooling device above may further include a return pipe. The return pipe may have one end thereof in communication with a top of the separation tank, and one other end thereof in communication with the condensation zone of the cooling tank.

Accordingly, during the operation of the liquid cooling device of the present disclosure, even if air containing water-liquid vapor is mixed into the condensation zone of the cooling tank, the water-liquid separation module provided is capable of separating water-liquid in the separation tank from the mixed liquid condensed by the condensation module, and ensuring that water-liquid does not flow back to the cooling zone of the cooling tank, thereby effectively eliminating loss caused by water-liquid vapor mixed in the cooling liquid as well as recollecting and recycling the cooling liquid to reduce operation costs. Moreover, the operation of the water-liquid separation function above does not consume additional resources, and the water-liquid separation module has a simple structure that can be readily manufactured and assembled while requiring minimal maintenance, providing high installation efficiency, wide application, and ideal practicability.

### BRIEF DESCRIPTION OF THE DRAWINGS

FIG. 1 is a partial structural side section diagram according to an embodiment of the present disclosure.

FIG. 2 is a schematic diagram of a normal operation according to an embodiment of the present disclosure.

FIG. 3 is a schematic diagram of an operation to discharge water-liquid according to an embodiment of the present disclosure.

FIG. 4 is a perspective structural schematic diagram according to an embodiment of the present disclosure.

FIG. 5 is an enlarged partial diagram of FIG. 4.

### DETAILED DESCRIPTION OF THE INVENTION

To facilitate understanding of the object, characteristics and effects of this present disclosure, embodiments together with the attached drawings for the detailed description of the present disclosure are provided.

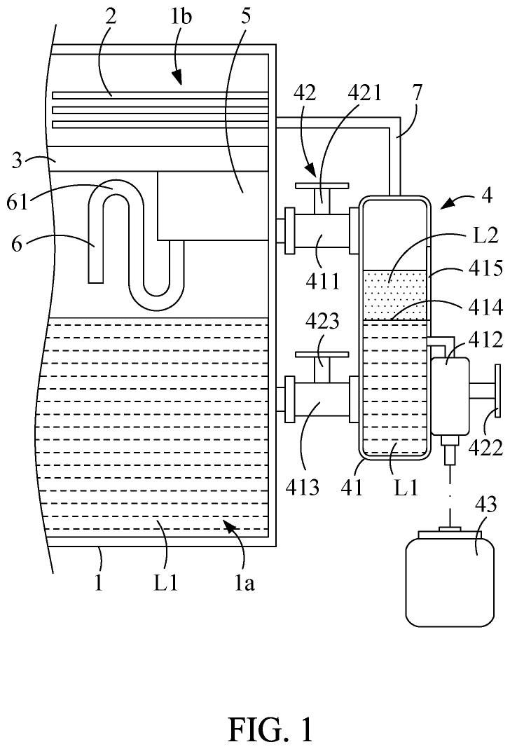

Referring to FIG. 1 showing a liquid cooling device according to a preferred embodiment of the present disclosure. The liquid cooling device includes a cooling tank 1, a condensation module 2, a liquid collection tank 3 and a water-liquid separation module 4. The cooling module 2, the liquid collection tank 3, and the water-liquid separation module 4 are all disposed in the cooling tank 1.

More specifically, the cooling tank 1 has a cooling zone 1a and a condensation zone 1b at an interior thereof. The cooling zone 1a may be configured to accommodate a cooling liquid L1 in a liquid state, and the condensation zone 1b is located above the cooling zone 1a. The condensation module 2 is disposed in the condensation zone 1b, and may be, for example, a cooling component such as a copper pipe that can be configured to condense a gaseous fluid to a liquid state. Thus, when a gaseous fluid in the condensation zone 1b is mixed with water-liquid vapor, a condensed liquid is a mixed liquid containing the cooling liquid L1 and water-liquid L2. The liquid collection tank 3 is located above the cooling zone 1a and is configured to receive a liquid condensed by the condensation module 2. The condensation module 2 may be completely perpendicularly projected within a range of the liquid collection tank 3, so that the liquid condensed by the condensation module 2 can entirely flow into the liquid collection tank 3.

The water-liquid separation module 4 includes a separation tank 41 and a valve assembly 42. The separation tank 41 from top to bottom includes a mixed liquid inlet section 411, a water-liquid outlet section 412 and a cooling liquid outlet section 413. The present disclosure does not specifically define the form of the separation tank 41. The form of the separation tank 41 may be modified to match a cabinet to be assembled to, and is in principle designed to be able to securely set up the components such as the valve assembly 42. In an embodiment of the present disclosure, the separation tank 41 in principle is formed as a sealed tank, and each of the mixed liquid inlet section 411, the water-liquid outlet section 412 and the cooling liquid outlet section 413 can be formed to have a joint pattern that can be readily connected to pipes or a pipe with one end in communication with the interior of the separation tank 41. That is, the separation tank 41 may be designed and selected by a person of ordinary skill in the art according to assembly requirements, and is not limited to the pattern disclosed in the drawings.

Moreover, the separation tank 41 has a boundary line 414, the mixed liquid inlet section 411 is higher than the boundary line 414, and the water-liquid outlet section 412 and the cooling liquid outlet section 413 are lower than the boundary line 414. The boundary line 414 is in principle at a dividing position between layers differentiated as water-liquid and other liquids in the mixed liquid flown into the interior of the separation tank 41. However, in practice, the dividing position may not be precisely predicted, so a range of the dividing position may be selected according to the rule of thumb. Moreover, the boundary line 414 is located within the range of the dividing position, the mixed liquid inlet section 411 is disposed at a position higher than the range of the dividing position, and the water-liquid outlet section 412 and the cooling liquid outlet section 413 are disposed at positions lower than the range of the dividing position.

The valve assembly 42 includes a first valve 421 disposed at the mixed liquid inlet section 411, a water-liquid drain valve 422 disposed at the water-liquid outlet section 412, and a second valve 423 disposed at the cooling liquid outlet section 413. Each of the first valve 421, the drain valve 422 and the second valve 423 may be, for example but not limited to, a manual valve or an electric valve.

The water-liquid separation module 4 is in communication with the liquid collection tank 3 via the mixed liquid inlet section 411, and is in communication with the cooling zone 1a via the cooling liquid outlet section 413. Thus, using the principle of connecting pipe, the separation tank 41 is able to have the boundary line 414 be at an equal height as a liquid level of the cooling liquid L1 in the cooling zone 1a.

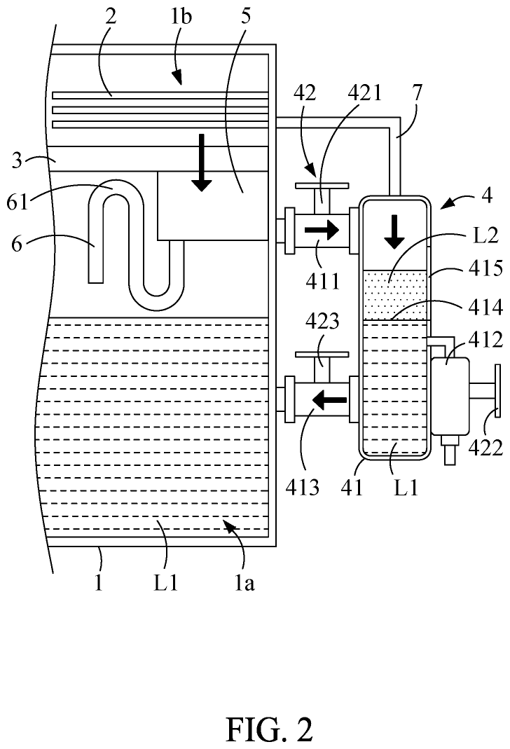

Accordingly, referring to FIG. 2, in a normal state of use, the first valve 421 and the second valve 423 are normally opened, and the drain valve 422 is normally closed. When the gaseous liquid in the condensation zone 1b is mixed with water-liquid vapor, the mixed liquid condensed by the condensation module 2 may be dripped into the liquid collection tank 3 and flow into the interior of the separation tank 41 via the mixed liquid inlet section 411, and the cooling liquid L1 and the water-liquid L2 in the mixed liquid can be naturally separated into layers based on a density difference; that is, the water-liquid L2 having a lower density is located at an upper layer, and the cooling liquid L1 having a higher density is located at a lower layer. The cooling liquid L1 located at the lower layer, once having accumulated to the liquid level of the cooling liquid L1 in the cooling zone 1a, may flow back based on the principle of connecting pipe via the cooling liquid outlet section 413 to the cooling zone 1a of the cooling tank 1, while the water-liquid L2 remains and continues accumulating at the interior of the separation tank 41.

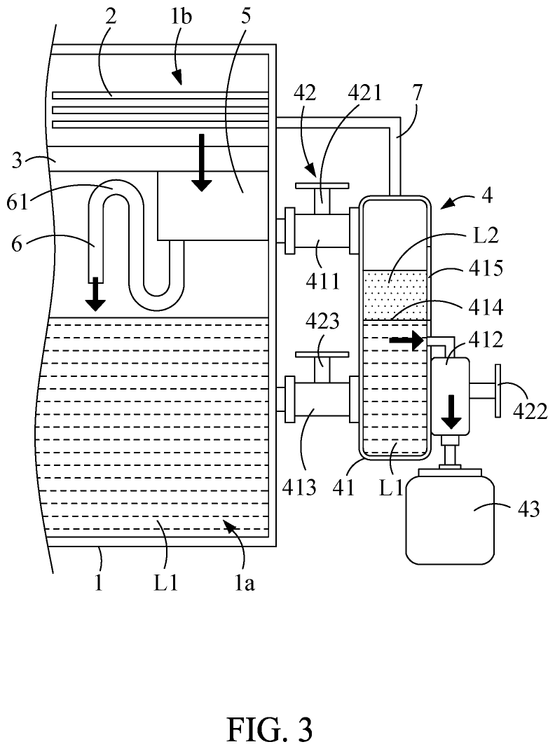

Referring to FIG. 3, to take out the water-liquid L2 accumulated in the separation tank 41, the first valve 421 and the second valve 423 are changed to a closed state and the drain valve 422 is controlled to be opened, so that the water-liquid L2 accumulated in the separation tank 41 is allowed to be discharged via the drain valve 422.

Thus, when an upper lid of the cooling tank 1 is opened and covered by an outer hood during maintenance or element replacement of the liquid cooling device, even if air containing water-liquid vapor in the outer hood is mixed into the condensation zone 1b, the liquid cooling device is capable of separating the water-liquid L2 from the mixed liquid condensed by the condensation module 2 by the water-liquid separation module 4, and discharging the condensed water-liquid L2 remaining in the separation tank 41, thereby ensuring that the condensed water-liquid L2 does not flow back into the cooling zone 1a of the cooling tank 1.

Accordingly, when the liquid cooling device is applied as a two-phase immersion cooling device for cooling an electronic device, the risk of electrical conduction due to condensed water-liquid can be effectively eliminated to maintain the quality of the cooling liquid L1 as well as normal operations of the electronic device. In particular, the operation of the above function of separating the water-liquid L2 does not consume additional resources, and the water-liquid separation module 4 has a simple structure that can be readily manufactured and assembled while requiring minimal consumables or infrequent maintenance after assembly. Thus, the liquid cooling device installed with the water-liquid separation module 4 is not burdened with additional resource costs caused by the operation of the function for filtering out the water-liquid L2, provides an extra guarantee, and once and for all eliminates loss derived by the water-liquid L2 mixed in the cooling liquid L1. Meanwhile, the life cycle of the cooling liquid L1 is increased to further reduce the overall operation costs of the liquid cooling device.

Referring to FIG. 1, in addition to the embodiments above, in one embodiment of the present disclosure, the water-liquid outlet section 412 may be disposed at a position slightly lower than the boundary line 414. Thus, when the water-liquid L2 at the interior of the separation tank 41 is discharged, the cooling liquid L1 in a small amount is together discharged, so as to ensure that the water-liquid L2 at the interior of the separation tank 41 is completely discharged.

In addition to the embodiments above, in one embodiment of the present disclosure, the separation tank 41 may include an inspection window 415. The inspection window 415 may be located between the first valve 421 and the second valve 423, and may be at least partially higher than the boundary line 414. Thus, when a user observes through the inspection window 415 from the outside of the separation tank 41 that there is the water-liquid L2 accumulated at the interior of the separation tank 41, the user may perform the above operation of discharging the water-liquid L2, hence providing an effect of ease of use. For example, the inspection window 415 may be transparent glass or acrylic disposed on a side opening of the separation tank 41. Alternatively, in other embodiments, the separation tank 41 may be selectively formed of a transparent material, so as to readily observe whether the water-liquid L2 is accumulated in the separation tank 41.

In addition to the above embodiments, in an embodiment of the present disclosure, the water-liquid separation module 4 may further include a liquid retrieval container 43. The liquid retrieval container 43 is detachably combined at the water-liquid outlet section 412, and whether the liquid retrieval container 43 is in communication with the interior of the separation tank 41 may be controlled by the drain valve 422. Thus, the ease of use during discharging of the water-liquid L2 in the separation tank 41 can be improved, and a situation of wetting an environment by splashing of a liquid can be reduced. In particular, when a liquid discharged contains a small amount of the cooling liquid L1, the cooling liquid L1 can be prevented from volatilizing into gases with environmental pollution or safety hazards and from spilling into a working environment of personnel, hence provided an effect of improving operation safety of personnel.

In addition to the above embodiments, in an embodiment of the present disclosure, the liquid cooling device may further include a storage tank 5, which indirectly communicates the mixed liquid inlet section 411 of the water-liquid separation module 4 with the liquid collection tank 3. That is, the storage tank 4 is located in the cooling tank 1 and is in communication with the liquid collection tank 3 and located below the liquid collection tank 3, and the mixed liquid inlet section 411 may be in communication with a lower half of the storage tank 5. Thus, the liquid condensed by the condensation module 2 first flows into the liquid collection tank 3 and then flows into the storage tank 5, and flows into the interior of the separation tank 41 via the mixed liquid inlet section 411 when the first valve 421 is opened. When the first valve 421 is closed, since the liquid condensed by the condensation module 2 can first be temporarily accumulated in the storage tank 5, the liquid can be temporarily accumulated in a space provided by the storage tank 5 to prevent the liquid from overflowing the liquid collection tank 3.

In an embodiment of the present disclosure, the liquid cooling device may further include an S-shaped bend pipe 6. The S-shaped bend pipe 6 is located in the cooling tank 1, and has one end thereof in communication with the lower half of the storage tank 5. The S-shaped bend pipe 6 has an uppermost part 61 between two ends thereof, and the uppermost part 61 may be aligned with an upper half of the storage tank 5. Accordingly, since mixed liquid accumulated in the storage tank 5 can be naturally separated into two layers based on the density difference between the cooling liquid L1 and the water-liquid L2, the cooling liquid L1 having a higher density and located at the lower layer further enables the liquid height of the cooling liquid L1 in the storage tank 5 to be equal to the liquid height of the cooling liquid L1 in the S-shaped bend pipe 6. Moreover, the cooling liquid L1 in the storage tank 5 overflows toward a free end of the S-shaped bend pipe 6 when the liquid height of the cooling liquid L1 in the storage tank 5 is higher than the uppermost part 61 of the S-shaped bend pipe 6, and flows back to the cooling zone 1a of the cooling tank 1 so as to be recycled, further ensuring that the water-liquid L2 in the storage tank 5 does not flow back to the cooling zone 1a of the cooling tank 1. Thus, even if the first valve 421 is closed over an extended period of time, the liquid condensed by the condensation module 2 does not overflow the liquid collection tank 3 or the storage tank 5, and part of the cooling liquid L1 can be guided back to the cooling zone 1a of the cooling tank 1 via the S-shaped bend pipe 6, so as to maintain the operation of the liquid cooling device. When the first valve 421 is switched back to be opened, most of the liquid in the storage tank 5 is allowed to flow into the separation tank 41 via the mixed liquid inlet section 411, so as to perform the operation of separating the water-liquid L2.

In addition to the embodiments above, in an embodiment of the present disclosure, the liquid cooling device may further include a return pipe 7. The return pipe 7 may have one end thereof in communication with a top of the separation tank 41, and the other end thereof in communication with the condensation zone 1b of the cooling tank 1. Thus, since a flowing liquid inevitably carries a certain amount of air, the air flown into the separation tank 41 along with the liquid is allowed to flow back to the condensation zone 1b of the cooling tank 1 via the return pipe 7, hence improving a filtering rate of the water-liquid L2 and maintaining the pressure balance at the interior of the separation tank 41.

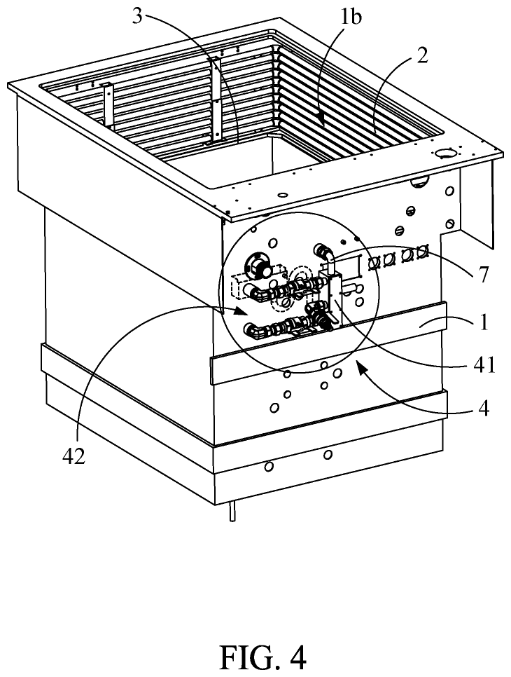

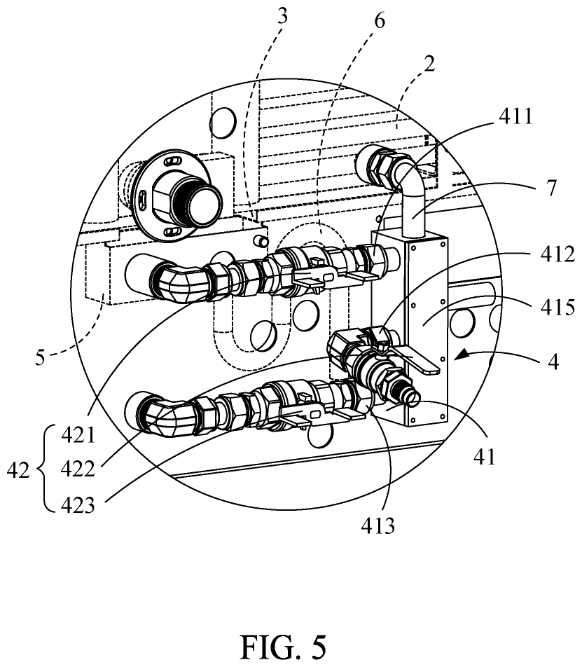

Referring to FIG. 4 and FIG. 5, in an embodiment of the present disclosure the condensation module 2 may be disposed as a loop along an inner tank wall of the cooling tank 1, and the liquid collection tank 3 may also be formed as a tank in a loop and be disposed below the condensation module 2. The liquid collection tank 3 may be appear slightly tilted and the storage tank 5 bears a lower part of the liquid collection tank 3, such that the liquid condensed by the condensation module 2 may drip into the liquid collection tank 3 and naturally flow into the storage tank 5 without any drive force. Moreover, when the first valve 421 is opened, most of the liquid in the storage tank 5 is allowed to flow into the separation tank 41 via the mixed liquid inlet section 411, so as to perform the operation of separating the water-liquid L2.

The present invention is described by way of the preferred embodiments above. A person skilled in the art should understand that, these embodiments are merely for describing the present invention are not to be construed as limitations to the scope of the present invention. It should be noted that all equivalent changes, replacements and substitutions made to the embodiments are to be encompassed within the scope of the present invention. Therefore, the scope of protection of the present invention should be accorded with the broadest interpretation of the appended claims.

What is claimed is:

1. A water-liquid separation module, comprising:
a separation tank, comprising from top to bottom a mixed liquid inlet section, a water-liquid outlet section and a cooling liquid outlet section, the separation tank having a boundary line, the mixed liquid inlet section being higher than the boundary line, the water-liquid outlet section and the cooling liquid outlet section being lower than the boundary line; and
a valve assembly, comprising a first valve disposed at the mixed liquid inlet section, a drain valve disposed at the water-liquid outlet section, and a second valve disposed at the cooling liquid outlet section.

2. The water-liquid separation module according to claim 1, wherein the water-liquid outlet section is disposed at a position slightly lower than the boundary line.

3. The water-liquid separation module according to claim 1, wherein the separation tank comprises an inspection window, which is located between the first valve and the second valve and is at least partially higher than the boundary line.

4. The water-liquid separation module according to claim 1, further comprising a liquid retrieval container detachably combined at the water-liquid outlet section, and the drain valve controls whether the liquid retrieval container is in communication with the interior of the separation tank.

5. A liquid cooling device, comprising:
a cooling tank, having a cooling zone and a condensation zone at an interior thereof, the cooling zone configured to accommodate a cooling liquid, and the condensation zone located above the cooling zone;
a condensation module, disposed in the condensation zone;
a liquid collection tank, located above the cooling zone, configured to receive a liquid condensed by the condensation module; and
the water-liquid separation module according to claim 1, in communication with the liquid collection tank via the mixed liquid inlet section, and in communication with the cooling zone via the cooling liquid outlet section.

6. The liquid cooling device according to claim 5, further comprising:
a storage tank, located in the cooling tank, in communication with the liquid collection tank and located below the liquid collection tank, wherein the mixed liquid inlet section is in communication with a lower half of the storage tank.

7. The liquid cooling device according to claim 5, further comprising:
an S-shaped bend pipe, located in the cooling tank and having one end thereof in communication with the lower half of the storage tank, the S-shaped bend pipe having an uppermost part between two ends thereof, wherein the uppermost part is aligned with an upper half of the storage tank.

8. The liquid cooling device according to claim 5, further comprising:
A return pipe, having one end thereof in communication with a top of the separation tank, and one other end thereof in communication with the condensation zone of the cooling tank.

9. A liquid cooling device, comprising:
a cooling tank, having a cooling zone and a condensation zone at an interior thereof, the cooling zone configured to accommodate a cooling liquid, and the condensation zone located above the cooling zone;
a condensation module, disposed in the condensation zone;
a liquid collection tank, located above the cooling zone, configured to receive a liquid condensed by the condensation module; and
the water-liquid separation module according to claim 2, in communication with the liquid collection tank via the mixed liquid inlet section, and in communication with the cooling zone via the cooling liquid outlet section.

10. The liquid cooling device according to claim 9, further comprising:
a storage tank, located in the cooling tank, in communication with the liquid collection tank and located below the liquid collection tank, wherein the mixed liquid inlet section is in communication with a lower half of the storage tank.

11. The liquid cooling device according to claim 9, further comprising:
an S-shaped bend pipe, located in the cooling tank and having one end thereof in communication with the lower half of the storage tank, the S-shaped bend pipe having an uppermost part between two ends thereof, wherein the uppermost part is aligned with an upper half of the storage tank.

12. The liquid cooling device according to claim 9, further comprising:
A return pipe, having one end thereof in communication with a top of the separation tank, and one other end thereof in communication with the condensation zone of the cooling tank.

13. A liquid cooling device, comprising:
a cooling tank, having a cooling zone and a condensation zone at an interior thereof, the cooling zone configured to accommodate a cooling liquid, and the condensation zone located above the cooling zone;
a condensation module, disposed in the condensation zone;
a liquid collection tank, located above the cooling zone, configured to receive a liquid condensed by the condensation module; and
the water-liquid separation module according to claim 3, in communication with the liquid collection tank via the mixed liquid inlet section, and in communication with the cooling zone via the cooling liquid outlet section.

14. The liquid cooling device according to claim 13, further comprising:
a storage tank, located in the cooling tank, in communication with the liquid collection tank and located below the liquid collection tank, wherein the mixed liquid inlet section is in communication with a lower half of the storage tank.

15. The liquid cooling device according to claim 13, further comprising:
an S-shaped bend pipe, located in the cooling tank and having one end thereof in communication with the lower half of the storage tank, the S-shaped bend pipe having an uppermost part between two ends thereof, wherein the uppermost part is aligned with an upper half of the storage tank.

16. The liquid cooling device according to claim 13, further comprising:
A return pipe, having one end thereof in communication with a top of the separation tank, and one other end thereof in communication with the condensation zone of the cooling tank.

17. A liquid cooling device, comprising:
a cooling tank, having a cooling zone and a condensation zone at an interior thereof, the cooling zone configured to accommodate a cooling liquid, and the condensation zone located above the cooling zone;
a condensation module, disposed in the condensation zone;
a liquid collection tank, located above the cooling zone, configured to receive a liquid condensed by the condensation module; and
the water-liquid separation module according to claim 4, in communication with the liquid collection tank via the mixed liquid inlet section, and in communication with the cooling zone via the cooling liquid outlet section.

18. The liquid cooling device according to claim 17, further comprising:
a storage tank, located in the cooling tank, in communication with the liquid collection tank and located below the liquid collection tank, wherein the mixed liquid inlet section is in communication with a lower half of the storage tank.

19. The liquid cooling device according to claim 17, further comprising:
an S-shaped bend pipe, located in the cooling tank and having one end thereof in communication with the lower half of the storage tank, the S-shaped bend pipe having an uppermost part between two ends thereof, wherein the uppermost part is aligned with an upper half of the storage tank.

20. The liquid cooling device according to claim 17, further comprising:
A return pipe, having one end thereof in communication with a top of the separation tank, and one other end thereof in communication with the condensation zone of the cooling tank.
